(19) United States
(12) Patent Application Publication
(10) Pub. No.: US 2024/0168087 A1
(43) Pub. Date: May 23, 2024

(54) Module for exchanging an interface unit, test system with such a module, method for testing semiconductor elements and for exchanging interface units

(71) Applicant: Turbodynamics GmbH, Stephanskirchen (DE)

(72) Inventor: Stefan Thurmaier, Bad Aibling (DE)

(21) Appl. No.: 18/512,234

(22) Filed: Nov. 17, 2023

(30) Foreign Application Priority Data
Nov. 18, 2022 (DE) 10 2022 130 631.3
Nov. 13, 2023 (DE) 10 2023 131 555.2

(51) Int. Cl. G01R 31/28

(52) U.S. Cl. CPC G01R 31/2893; G01R 31/2834

(57) ABSTRACT

The invention relates to a module for exchanging an interface unit in a test system with a handling unit and test unit for testing semiconductor elements. The module has a base element which is or can be attached to the test system, a holder for holding an interface unit, and guide elements which connect the holder to the base element. The guide elements are designed to guide the holder relative to the base element between the insertion position, in which the holder is located in the test system between the test unit and the handling unit, and the removal position, in which the holder is located outside an area between the test unit and the handling unit for exchanging the interface unit. Furthermore, at least one docking unit is provided, each with a docking element and a docking counter-element for coupling the holder to the base element in such a way that the coupling provides a rigid connection at least perpendicular to an interface plane. The docking element or the docking counter-element is attached to the holder and the docking counter-element or the docking element is attached to the base element, and the docking unit is designed for mechanically connecting and disconnecting the docking element to the docking mating element. The invention also relates to a test system with the module, methods for testing semiconductor elements and methods for exchanging interface units.

The invention relates to a module for exchanging an interface unit in a test system for testing semiconductor elements and a test system with such a module. The invention also relates to methods for testing semiconductor elements and for exchanging interface units.

Test systems for testing semiconductor elements generally comprise a test unit (“tester”) and a handling unit (“handler” or “prober”). The test unit comprises a test head, with which the semiconductor elements to be tested are contacted, and evaluation electronics. The handling unit comprises elements with which the semiconductor elements to be tested are successively fed to a test unit. So that different semiconductor elements can be tested with such a test system, there is an interface unit that is arranged in the area of the interface between the test unit and the handling unit and has contact elements for contacting the electrical semiconductor elements to be tested, on the one hand, and for contacting the test head, on the other. Depending on the test system, this interface unit can be attached either to the test unit or the handling unit. During operation, the test unit is firmly coupled to the handling unit. The interface unit is contacted by the test head of the test unit. The interface unit is loaded with a semiconductor element by the handling unit by contacting corresponding contact elements, which can then be tested by the test unit.

The term semiconductor elements includes semiconductor components and wafers. A handling unit for feeding individual integrated circuits is known in the trade as a “handler” and a handling unit for feeding wafers (wafer discs) is known as a “prober”. In a test system for testing wafers, the wafer discs are usually fed from below so that the handling unit is arranged below the test unit. The arrangement can therefore be rotated by 180°.

For testing semiconductor components, the interface unit usually has a base frame, an interface board (contacting plate) and a stiffening plate (so-called stiffener), which are firmly, but possibly detachably, connected to each other. The interface board has contact elements for contacting corresponding contact points on the semiconductor components as well as contacting patterns for contacting corresponding contact units of the test unit. The contact elements are each arranged in a pattern specific to the semiconductor components to be tested in order to be able to contact the contact points of the semiconductor components correctly, and are often designed as spring contacts. The contacting patterns are also arranged in a specific pattern in order to be able to contact the contact units of the test unit correctly and are connected to the contact elements via conductor tracks or other connecting elements. The base frame is designed to hold one or more semiconductor components and is provided with corresponding holding elements, such as alignment or centring elements and stop or support elements, in order to precisely position the semiconductor components in a clearly defined position relative to the interface board. The stiffening plate is designed to absorb pressure loads when the interface board is fitted with semiconductor components.

Different interface units are available for testing different semiconductor elements. The interface unit must therefore be exchanged if other semiconductor elements are to be tested. DE 10 2012 103 893 A1 (WO 2013/164407 A1), for example, discloses a test system for testing semiconductor elements with a module for exchanging an approximately flat interface unit, which comprises a base element that can be attached to the test system, a holder for holding an interface unit, and guide elements with which the holder is attached to the base element in such a way that the holder can be moved between an end position on the base element and a removal position, with the interface unit being located in an interface plane in the end position. The guide elements comprise at least one link-guided lever mechanism, which is designed at least for guiding a rectilinear translational movement of the holder a little in the direction perpendicular to the interface plane starting from the end position, and a drawer mechanism, which is designed for guiding a rectilinear translational movement of the holder in or parallel to the interface plane. Instead of directly attaching the interface unit to the test unit or the handling unit, the module is attached to the test unit or the handling unit with its base element. The interface unit can be moved via the guide elements between an insertion position, in which the interface unit for testing semiconductor elements is arranged between a test unit and a handling unit of the test system, and a removal position, in which the interface unit is arranged outside the area between the test unit and the handling unit.

When the interface unit is loaded with semiconductor components by the handling unit, this is done under comparatively high pressure, as the contact elements of the interface board are usually designed as spring contacts and are often present in large numbers. The spring forces of the contact elements must be reliably overcome in order to securely position and hold the semiconductor components. For this reason, the semiconductor components are pressed on under high pressure (so-called plunging). If the interface unit is also designed to hold several semiconductor components, the contact forces acting on the interface unit mount up. In total, forces of several 10 to several 100 or even several 1000 kg can occur. These forces are transferred to the guide elements that guide and, if necessary, move the holder relative to the handling unit or test unit for exchanging the interface unit and hold it in the test position during the test process. High forces can therefore act on the guide elements. These must therefore be designed to be very robust, as even slight wear can impair the accuracy of the positioning of the interface unit and holding forces can penetrate drive elements of the exchange module or the test head.

DE 10 216 003 B4 (U.S. Pat. No. 6,870,362 B2) discloses a docking device for coupling a first device consisting of a handler or prober and a second device consisting of a test head for electronic components, wherein at least one locking unit is provided which has an axial insertion opening for inserting a locking pin. A plurality of balls is arranged in the region of the insertion opening, between which the locking pin can be inserted. Furthermore, a ball clamping sleeve is provided, which causes a radial movement of the balls inwards by axial displacement, so that the balls engage in a circumferential groove of the locking pin and can thus secure it. The axial displacement can be triggered by a rotatable threaded sleeve, the internal thread of which meshes with an external thread of the ball clamping sleeve, which is mounted in a rotationally fixed but axially displaceable manner. The rotation of the threaded sleeve can be controlled via a cable pull.

In DE 10 2005 036 808 B4 (U.S. Pat. No. 7,382,145 B2), the above-mentioned docking device is further developed in that the axial displacement of the ball clamping sleeve can be triggered and controlled via a pressure medium. The ball clamping sleeve can be reset without pressure by at least one spring. A docking device of this type enables a particularly simple, easy and precise coupling of the handler or prober with the test head weighing up to 1000 kg.

Furthermore, DE 10 2012 112 271 A1 (WO 2014/091022 A1) discloses a merging or docking device for merging a first device consisting of a handler or a prober with a second device consisting of a test head for electronic components. The merging device can be attached to one of the first or second devices and comprises a latching device with a cylindrical pin receptacle for receiving and fixing by means of a latch a front end of a catch pin. The catch pin can be fastened to the other device accordingly, wherein the latching device is coupled to a linear displacement device in such a way that the cylindrical pin receptacle can be displaced linearly by means of the linear displacement device by at least one path which corresponds to several times the length of the front section of the catch pin which can be inserted into the pin receptacle. Furthermore, the latching device can be coupled to a linear displacement device in such a way that the latching element, the spring element and the pin receptacle of the latching device can be displaced linearly by means of the linear displacement device with the catch pin engaged. This ensures that the first device and the second device can be moved relative to each other.

U.S. Pat. No. 6,876,215 B1 describes a device for testing semiconductors in wafers using probe cards. The device comprises a probe card changer, which is designed for exchanging the probe cards. The probe card is inserted into a drawer (“probe card tray”) by means of a sliding mechanism. For testing, the probe card changer and a docking device (“pogo tower”) are brought together, whereby the docking device is connected to a test device (“test head”) via an interface. The test device has movable cams and has docking bars, each with a driver bearing that can be gripped by the cams in order to connect the docking bars and thus indirectly also lock the probe card changer to the test head, as the probe card changer is held by the docking bars.

One task of the present invention is to create a module for exchanging an interface unit in a test system, which can absorb high contact pressure forces on the interface unit very well and at the same time is very compact and simple in design and is very suitable for automation.

The task is solved by the features of the independent claims. Advantageous further embodiments are set out in the subclaims. Further advantages and advantageous embodiments of the invention are explained in the detailed description with reference to the accompanying drawings.

The invention is based on the idea of fixing an interface unit or its holder, which can be moved relative to a test system between a removal position and an insertion position, in the end position relative to the test system by means of a docking device.

On the basis of this consideration, according to a first aspect of the invention, a module for exchanging an interface unit in a test system with a handling unit and a test unit for testing semiconductor elements is provided, wherein the module has a base element which is attached or can be attached to the test system, a holder for receiving an interface unit and guide elements. The guide elements connect the holder to the base element and are designed to guide the holder relative to the base element between an insertion position, in which the holder is located in the test system between the test unit and the handling unit, and a removal position, in which the holder is located outside the area between the test unit and the handling unit for exchanging the interface unit. A coupling device is provided for coupling the interface unit to the base element, whereby the coupling device is either arranged between the holder and the base element for coupling the holder to the base element in such a way that the coupling device can form a rigid connection at least perpendicular to an interface plane, or the coupling device is arranged on the interface unit and on the base element so that the interface unit can be fixed to the base element.

The interface plane is a plane that contains the interface unit during operation. The interface plane can be defined in particular by a surface or other characteristic plane or area of a contacting plate (interface board) or a stiffening plate of the interface unit or as a plane defining the receiving elements of a base frame of the interface unit for receiving semiconductor components.

When using such a test system, the interface units must be exchanged regularly, as different semiconductor elements to be tested require correspondingly different interface units. To exchange an interface unit in the test system, the handling unit and the test unit are separated from each other and moved apart a little. The holder with the interface unit is then moved out of an intermediate position (inserted position) between the handling unit and the test unit into the removal position by means of the guide elements. Once it has been moved out to the removal position, the interface unit can be exchanged.

The holder with the newly inserted interface unit can then be moved back from the removal position into the intermediate position by means of the guide elements.

The holder with the interface unit is then moved from the intermediate position towards the base element and pressed against it. The base element is attached to one of the two units (handling unit or test unit). For example, the holder with the interface unit is moved and pressed against the base element by means of a scissor mechanism, as shown in DE 10 2012 103 893 A1 (WO 2013/164407 A1) (pressing mechanism). The scissor mechanism is in a fold-out position when the holder with the interface unit is in the intermediate position. The scissor mechanism is folded up in order to pull the holder with the interface unit towards the base element and press it against it. The scissor mechanism according to DE 10 2012 103 893 A1 is described in more detail in the embodiments of this application and shown by means of figures. After pressing the holder with the interface unit onto the base element, these are in an end position. The handling unit and the test unit are then moved together again and the interface unit is fixed between them. The position that the holder with the interface unit assumes after the handling unit and the test unit have been moved together is referred to as the test position.

The test position is the position in which the holder holds the interface unit in relation to the handling unit so that the latter can fit the interface unit with semiconductor elements.

In the present invention, either the holder or the interface unit is fixed to the base element (end position) by means of the coupling device after pressing the holder with the interface unit against the base element before the handling unit and the test unit are moved together. This has the advantage that the interface unit is in a defined position in relation to the handling unit or the test unit when it is moved together and the pressure mechanism (e.g., a scissor mechanism or lifting cylinder) does not have to be under tension in order to hold the interface unit in the desired position. This means that the handling unit and the test unit do not have to work against the tension of the pressure mechanism (scissor mechanism or lifting cylinder) when they are moved together, and it is easier to move them together while the interface unit is reliably positioned. This means that only two elements (handling unit and test unit) and not three elements (handling unit, test unit and interface unit) are movable when moving together.

When the interface unit is loaded with semiconductor elements by the handling unit, this is done under comparatively high pressure, as contact elements of a contacting plate of the interface unit are usually designed as spring contacts and are often present in large numbers. The spring forces of the contact elements must be reliably overcome in order to securely position and contact the semiconductor components. For this reason, the semiconductor elements are pressed on under high pressure (so-called plunging). Normally, some of this pressure on the interface unit must be absorbed by the pressure mechanism (scissor mechanism) and the guide elements. By providing the coupling device, which fixes either the holder or the interface unit to the base element, the pressure is absorbed by the coupling device and the pressure mechanism is relieved. This means that the pressure mechanism can be designed to be less stable, which reduces the weight of the module.

In contrast, the document U.S. Pat. No. 6,876,215 B1 shows a device in which coupling elements are provided on a handling unit and on a test unit. These coupling elements serve to connect the handling unit to the test unit, but they do not serve to fix an interface unit to the test unit.

The coupling device can be designed as at least one docking unit each with a docking element and a docking counter-element for coupling the holder of the holder to the base element in such a way that the coupling device provides a rigid connection at least perpendicular to the interface plane, wherein the docking element or the docking counter-element is attached to the holder and the docking counter-element or the docking element is attached to the base element and the docking unit is designed for mechanically connecting and disconnecting the docking element to the docking counter-element.

In the embodiment with the docking elements, the holder can be rigidly coupled to the base element due to the docking elements in an end position. Since the holder carries the interface unit and the base element is rigidly connected to the test system, i.e., the test unit and/or the handling unit, the interface unit can thus be rigidly locked in relation to the test system, i.e., in relation to the test unit and/or the handling unit. This means that a module for exchanging an interface unit in a test system can be provided that can absorb high contact forces on the interface unit very well and is also very compact and simple. The contact forces can be effectively kept away from moving elements, drive elements or the test head. As the holder is docked onto the base element, the exchange module and docking units can be provided and installed as a complete unit. Only the base element needs to be mounted on the handling unit or the test unit, and all positional relationships are defined in the exchange module. The function of the docking elements as well as all movements of the guide elements can be performed or initiated manually, mechanically and, if necessary, automatically.

In this configuration of the coupling device by means of the docking elements, the holder can be coupled to the base element and brought very close to the base element. This is due to the fact that the respective docking elements can engage deeply into the corresponding docking counter-elements, which means that there is no gap between the interface unit and the base element due to a possible premature stop of the docking elements on the docking counter-elements.

This means that neither the semiconductor elements to be tested, which are provided by means of the handling unit of the interface unit, nor the test unit itself need to be moved despite the coupling of the holder to the base element for the actual test process by means of the test unit. If the components to be tested had to be moved a little for each test in order to be tested (indexing), somewhat more time would be required for each test. With many hundreds or thousands of consecutive tests of the same components, this can lead to a considerable delay. This configuration of the coupling device is therefore particularly advantageous for testing large series of identical components.

Possible differences in the thicknesses of the interface units can be equalised by manually setting a distance between the docking elements and docking counter-elements.

Preferably, the guide elements have a drawer mechanism for linear guidance of the holder relative to the base element similar to a drawer in a first direction of movement. The first direction of movement preferably runs in or parallel to the interface plane. The drawer mechanism preferably has a telescopic rail, in particular a pair of telescopic rails. The telescopic rail can have a running rail, which carries the holder, and a guide rail, which guides the running rail. With such a drawer mechanism, the holder can be brought into the removal position particularly easily and efficiently with a compact design and simple mechanics in order to exchange interface units.

Preferably, the guide elements can have a lifting mechanism for linear guidance of the holder relative to the base element in a second direction of movement, wherein the first direction of movement is substantially perpendicular to the first direction of movement and preferably substantially perpendicular to the interface plane. In particular, the lifting mechanism may have a lever mechanism, such as a universal joint (also referred to as a scissor mechanism), toggle joint or the like. To move the lever mechanism, lever bearings can be provided, which can have a fixed bearing for fixed swivel joints on the one hand and one or more slotted holes for movable swivel joints on the other. Such a lever mechanism can be driven by a cable, chain or belt drive, by link rods, pistons or articulated motors. The drive can act on a longitudinally displaceable link that has guide tracks for bolts or other projections on the lever mechanism. Manual actuation is just as conceivable as automatic or semi-automatic operation. It should be mentioned that the second direction of movement can ideally be perpendicular to the first direction of movement, but can also have a portion along the first direction of movement if, for example, a lever mechanism specifies this. However, it is preferable to ensure that the proportion of the second direction of movement along the first direction of movement is small. The stroke of the lifting mechanism can be comparatively small and only needs to be sufficient to separate the docking units from each other and bring the holder into the removal position.

In embodiments, a drive mechanism can be provided for motorised, in particular automatically or semi-automatically controlled, movement of the holder relative to the base element under the guidance of the guide elements. The drive can only affect the drawer mechanism or only the lifting mechanism or both. It is therefore possible to design the module from fully manual to fully motorised with regard to the actuation of the guide elements.

Preferably, several docking units are provided for connecting the drawer unit and the base element. Even if a connection with only one docking unit is possible, it is advantageous if two, three, four or more docking units are provided. The docking units are preferably provided as close as possible to the guide elements in order to keep loads away from them as effectively as possible when locked. Two docking units enable symmetrical coupling, for example in the vicinity of each pair of telescopic rails. Three docking units can clearly define a coupling level, whereby, for example, two docking units are provided at the front or rear next to the telescopic rails and the third docking unit is provided at the rear or front in the centre. Load distribution can be optimised with four docking units. These can, for example, be arranged at the edge of the holder near the four corners. Further docking units can be provided at the edge between corners of the bracket, for example, in order to reduce the loads on each docking unit and/or to stiffen the bracket.

In embodiments, the docking units can be actuated for connection or disconnection mechanically and/or pneumatically and/or electrically and/or magnetically, in particular electromagnetically. This means that the docking units can also be integrated into an automation and/or partial automation of the test system and the locking can be carried out reliably. Alternatively or additionally, manual actuation is also conceivable.

Preferably, the docking element of each docking unit can have a locking pin and the docking counter-element of each docking unit can have a locking element that engages in a catch provided on the locking pin. In particular, the catch can be designed as a circumferential groove.

The locking element can have a gripping mechanism that engages in the catch. The gripping mechanism can preferably have a plurality, in particular at least three, balls, between which the locking pin can be inserted, and a ball clamping sleeve that can be displaced in the axial direction, which can fix the balls in the catch or release them from the catch by axial displacement. This is a known and proven design of such a docking unit. Other forms of gripping mechanism, for example in the form of a lever arrangement, are also conceivable.

In embodiments, the gripping mechanism can be connected to a pulling mechanism, which is designed to pull the gripping mechanism along an axis of the locking pin. A drive can be provided that affects the pulling mechanism and/or the gripping mechanism. In principle, both can also be actuated by separate and/or different mechanisms. The gripping mechanism and the pulling mechanism can be actuated separately from each other in sequence. It is understood that the pulling mechanism can act in both axial directions to pull the locking pin towards the docking counter-element, on the one hand, and to push the locking pin away from the docking counter-element, on the other hand. The pulling mechanism can be designed in such a way that the locking pin is pressed against a stop in an end position so that a particularly firm and rigid connection can be created. The pulling mechanism for axially displacing the locking pin can also be designed to perform other operations. For example, when all docking units are actuated synchronously, the pulling mechanism can move the holder in the second direction of movement by a certain distance towards or away from the base element. The path achieved in this way can be limited to a final stroke. The final stroke may, for example, include a path for contacting/separating connecting elements between the interface unit and the test unit. The remaining stroke can be realised by other drive means. However, the path achieved by the pulling mechanism can also cover the entire stroke of the lifting mechanism. In this way, a drive for the lifting mechanism can be fully realised by the docking units. Lever mechanisms can possibly be replaced by simple linear, vertical slotted guides, which can significantly simplify the lifting mechanism. It should be mentioned that several defined positions can be provided between the inserted position and the end position or test position of the holder, which can be separately sensed by corresponding sensors and which, when reached, can trigger separate processes such as locking or confirmation of the connection. Such positions and sensor systems are described, for example, in DE 10 2021 114 564 A1 (US 2022/390508 A1), to the disclosure of which reference is made in full in this regard.

The base element can be attached to the test unit or the handling unit. The base element can have an outer frame and an inner frame, whereby the outer frame is attached or can be attached to the test unit or the handling unit, and whereby the inner frame is attached or can be attached to the outer frame. A base element with such a modular design can be adapted to different holders by exchanging the inner frame without requiring complete separation from the test system. In particular, the docking counter-element of the at least one docking unit can be attached or attachable to the inner frame. This inner frame can be exchanged for another inner frame without a docking counter-element if a holder without a docking element is used. The inner frame can also be removed to replace or maintain the docking counter-elements.

The holder can be any device that is designed to hold the interface unit securely. In particular, the holder can have a holding frame, whereby the interface unit can be held in a holding opening (window) formed by the holding frame. Other forms, such as a retaining plate, retaining clip, retaining fork or similar are also conceivable. As described above, the interface unit can have a stiffening plate (stiffener), a contacting plate (interface board) and a base frame. The interface unit can be attached to the holding frame via counter bearings, which are preferably arranged on the stiffener plate so that the contacting plate itself remains free of bending and torsion. To accommodate an interface unit, the holding frame can have at least two supports arranged opposite each other. The supports can protrude into the mounting opening. The supports and counter-supports can have centring pins or openings, locking elements, positive locking elements or the like.

In embodiments, a bridge element can be provided, which is attached or can be attached spanning the holding opening of the holding frame and which is designed to hold or support an interface unit or an interface unit carrier or a stiffening plate (stiffener). The bridge element can be a cast or milled part made of aluminium or steel or another metallic material or a moulded part made of plastic or carbon, possibly fibre-reinforced, or a milled part. The bridge element is preferably designed to be as rigid as possible against deflection. The bridge element can absorb bending loads from the interface unit. This makes it possible to make the interface unit, in particular a stiffening plate of the same, lighter. It also makes it possible to apply a higher pressure load to the interface unit during plunging.

Furthermore, locking elements can be provided on the holding frame to lock the interface unit to the holding frame. The locking elements can preferably comprise spring-loaded latching catches. The latching catches can be actuated against the spring force to release the bridge element and can have an insertion ramp for contact with parts of the interface unit, in particular a stiffening element of the same. This allows the latching catch to be pushed back during assembly by sliding on the insertion ramp against the spring force and then snap back when the insertion ramp has been overcome. The latching catch can be released manually, mechanically or by motor to remove the interface unit.

The coupling device may comprise an adapter frame with at least one recess and at least one movable coupling element for coupling the interface unit to the base element such that the coupling provides a detachable positive connection parallel to the interface plane, wherein the adapter frame is attached to the interface unit and at least one movable coupling element is attached to the base element, and wherein the movable coupling element engages in the recess to establish a detachable mechanical connection between the interface unit and the base element.

In this configuration of the coupling device, it is also provided that the holder with the interface unit is moved from the intermediate position (insertion position), in which the holder with interface unit is located in the test system between the test unit and the handling unit, to an end position on the base element. The holder with the interface unit is moved from the inserted position to the end position using the scissor mechanism, for example. In the end position, the holder with the interface unit is pressed back against the base element, with the scissor mechanism in a folded position.

In this embodiment, the end position is a position in which the adapter frame, which is arranged on the interface unit, extends through an opening in the base element and abuts against the handling unit. In this position, the movable coupling elements on the base element can engage in the recesses of the adapter frame in order to couple the adapter frame and thus the interface unit to the base element.

Both the adapter frame as well as the recesses and the movable coupling elements are preferably as flat as possible in a direction perpendicular to the interface plane. Only the structure with the coupling elements that move parallel to the interface plane and the correspondingly arranged recesses enable such a flat design of these elements, which ensure that the interface unit is fixed to the base element.

The combination of the scissor mechanism to move the holder with the interface unit from the inserted position to the end position and a flat design of the elements that fix the interface unit to the base element enables a flat design of the module (comprising the holder with the interface unit and the base element).

With such a coupling device, little space is required for the module between the handling unit and the test unit, as the holder with the interface unit requires little space to be inserted between the test unit/handling unit and the base element. This means that the handling unit and the test unit only need to be moved slightly apart when the holder with the interface unit is exchanged and moved out into the removal position.

At the same time, the holder with the interface unit only needs to be moved a short distance in order to be transferred from the inserted position to the end position. This means that the module is very flat and compact even when the holder with the interface unit is in the inserted position.

If both the test unit and the handling unit do not have to be moved so far apart and the holder with the interface unit does not have to be moved so far in order to be transferred from the inserted position to the end position, the interface units can be exchanged quickly and easily. This is particularly advantageous if smaller series of semiconductor elements are to be tested, which all require different interface units for the test process.

Each interface unit comprises a base frame, a contacting plate (interface board) and a stiffening plate (stiffener). The base frame is designed to hold one or more semiconductor components and is provided with corresponding holding elements, such as alignment or centring elements and stop or support elements. The contacting plate has contact elements (usually spring-loaded contact pins, which are also known as pogo pins) for contacting corresponding contact points on the semiconductor components as well as contacting patterns for contacting corresponding contact units of the test unit.

When using the test system, it is often necessary to use base frames of different thicknesses. The reason for this is that semiconductor components of different sizes and thicknesses require different base frames in order to be able to be accommodated appropriately. The base frames can have different thicknesses of several millimetres.

In this configuration of the coupling device, the interface units are moved until the adapter frame and the base frame extend through an opening in the base element and the adapter frame abuts against the handling device. The thickness of the base frame is irrelevant here. The distance from the interface unit to the handling device is always determined by the thickness of the adapter frame. This means that the interface units can be quickly exchanged and fixed (and thus put into operation) without having to make any further (manual) adjustments to the holder, the interface unit or the base element in order to compensate for the differences in the thicknesses of the base frames.

The adapter frame can have several recesses. A number of movable coupling elements can also be provided on the base element, with one coupling element being provided for each recess.

The recesses can be through-holes or blind holes, for example, into which the movable coupling elements can engage precisely. The coupling elements can be latches, for example, which are moved by means of a lifting cylinder. The recesses are arranged on the side of the adapter frame so that the coupling elements can be brought into engagement with the recesses by moving them horizontally.

The exchange module comprising the holder, the guide elements and the base element can be designed as an independent unit.

The exchange module can therefore be retrofitted to or removed from an existing test system.

According to a further aspect of the invention, a test system with a handling unit and a test unit for testing semiconductor elements is provided, wherein the test system comprises the module described above.

Since the test system has the module according to the invention, the same effects can be achieved by the test system. The test system with the module is highly reliable, compact and automatable.

According to a further aspect of the invention, a method for testing semiconductor elements by means of a test system is provided. The test system comprises a test unit, a handling unit for handling semiconductor elements and a module for exchanging interface units. The module (exchange module) comprises a base element that is attached to the test system, a holder for holding an interface unit, and guide elements. The guide elements connect the holder to the base element and are designed to guide the holder relative to the base element between an inserted position, in which the holder is located in the test system between the test unit and the handling unit, and a removal position, in which the holder is located outside the area between the test unit and the handling unit for exchanging the interface unit. The module can be designed in particular according to the first aspect of the invention described above with its embodiments and variants. The method comprises the steps of:
picking up an interface unit in the holder located in the removal position;
moving the holder with the interface unit into the insertion position;
moving the holder with the interface unit from the inserted position to an end position on the base element;
coupling the interface unit to the base element by means of a coupling device, wherein the coupling device either
   is arranged between the holder and the base element for coupling the holder to the base element in such a way that the coupling device can form a rigid connection at least perpendicular to an interface plane, or
   the coupling device is arranged on the interface unit and on the base element so that the interface unit can be fixed to the base element;
moving the handling unit and the test unit together;
placing at least one semiconductor element on the interface unit by means of the handling unit;
testing at least one semiconductor element by means of the test unit; and
removing at least one semiconductor element from the interface unit by means of the handling unit, wherein the steps of placing, testing and removing are preferably repeated for a plurality of at least one semiconductor element.

Since the method makes use of the module according to the invention, the same effects can be achieved by the method. The method is particularly reliable, simple and fast and can be automated to a high degree.

Before locking the holder to the base element by means of at least one docking unit, a stroke perpendicular to the interface level can be performed by a lifting mechanism or by the docking unit itself.

According to a further aspect of the invention, a method for exchanging interface units on a test system is provided. The test system comprises a test unit, a handling unit for handling semiconductor elements and a module for exchanging interface units. The module (exchange module) comprises a base element that is attached to the test system, a holder for holding an interface unit, and guide elements. The guide elements connect the holder to the base element and are designed to guide the holder relative to the base element between an inserted position, in which the holder is located in the test system between the test unit and the handling unit, and a removal position, in which the holder is located outside the area between the test unit and the handling unit for exchanging the interface unit. The module can be designed in particular according to the first aspect of the invention described above with its embodiments and variants. The method comprises the steps of:
releasing the holder located
   in an end position with the interface unit from the base element by releasing a coupling state of a coupling device, wherein the coupling device either
   is arranged between the holder and the base element for coupling the holder to the base element in such a way that the coupling device can form a rigid connection at least perpendicular to an interface plane, or
   the coupling device is arranged on the interface unit and on the base element so that the interface unit can be fixed to the base element;
moving the holder with the interface unit from the end position to the inserted position;
moving the holder with the interface unit to the removal position;
removing the interface unit from the holder;
picking up another interface unit in the holder;
moving the holder with the other interface unit to the inserted position;
moving the holder with the other interface unit to the end position on the base element; and
locking the holder with the other interface unit to the base element by means of the coupling device.

Since the method makes use of the module according to the invention, the same effects can be achieved by the method. The method is particularly reliable, simple and fast and can be automated to a high degree.

Before locking the holder to the base element by means of at least one docking unit, a stroke perpendicular to the interface level can be performed by a lifting mechanism or by the docking unit itself.

The invention is explained in more detail below by way of example with reference to the drawings. The drawings show in:

FIG. 1a Test system in a perspective view with a module according to the invention for exchanging an interface unit,

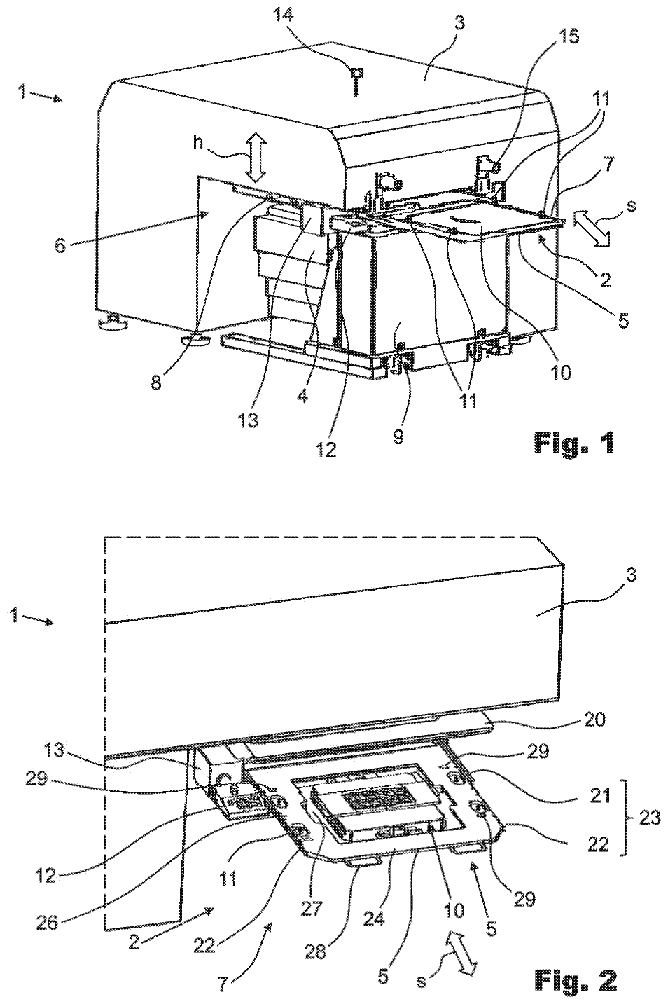

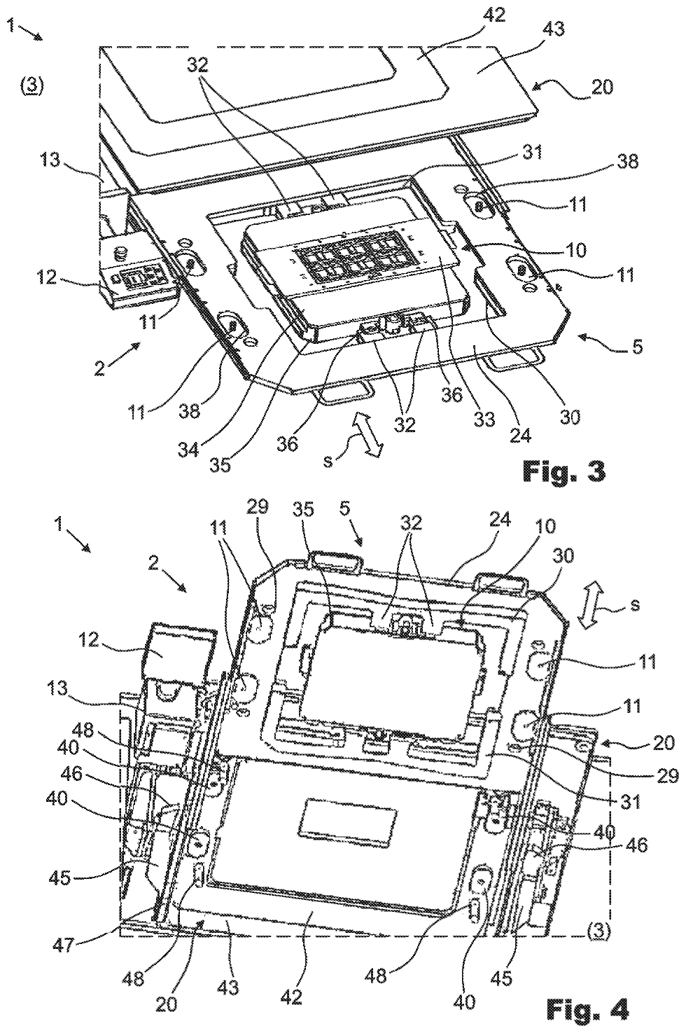

FIG. 2 The test system from FIG. 1 with the module in a first design variant in a removal position in a perspective view from above,

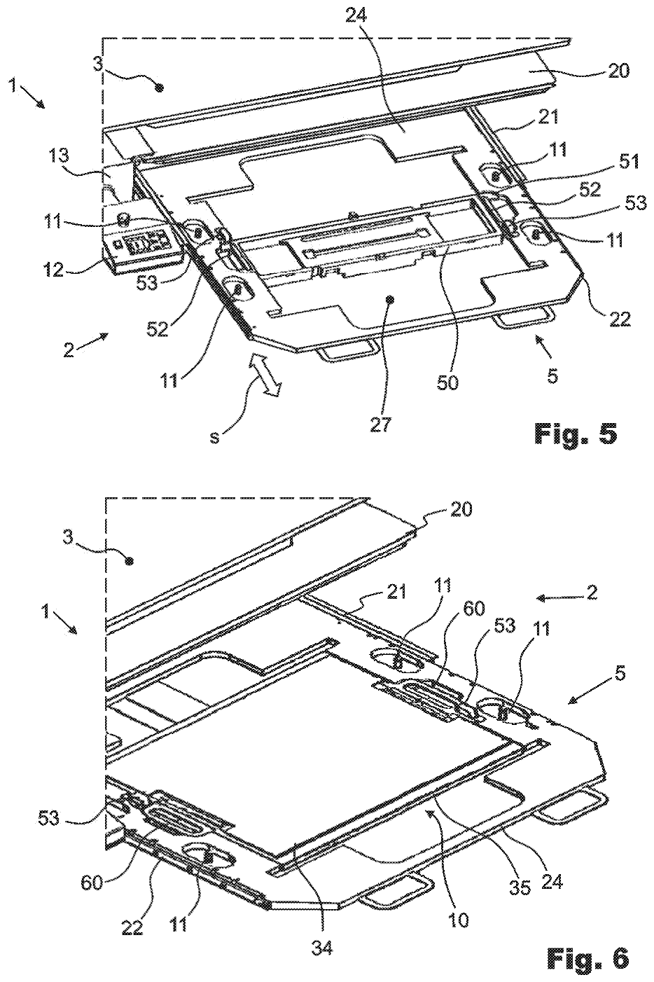

FIG. 3 The test system from FIG. 2 in a further perspective view from above,

FIG. 4 The test system from FIG. 2 in a perspective view from below,

FIG. 5 The test system from FIG. 1 with the module in a second design variant in a removal position in a perspective view from above without interface unit,

FIG. 6 The test system from FIG. 5 with the interface unit fitted,

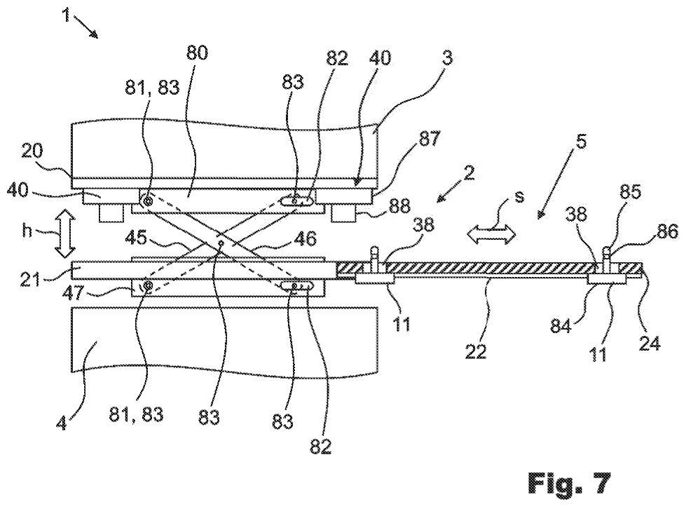

FIG. 7A schematic, partially sectioned side view of the test system of FIGS. 1 to 6 to illustrate a basic functional principle according to the invention,

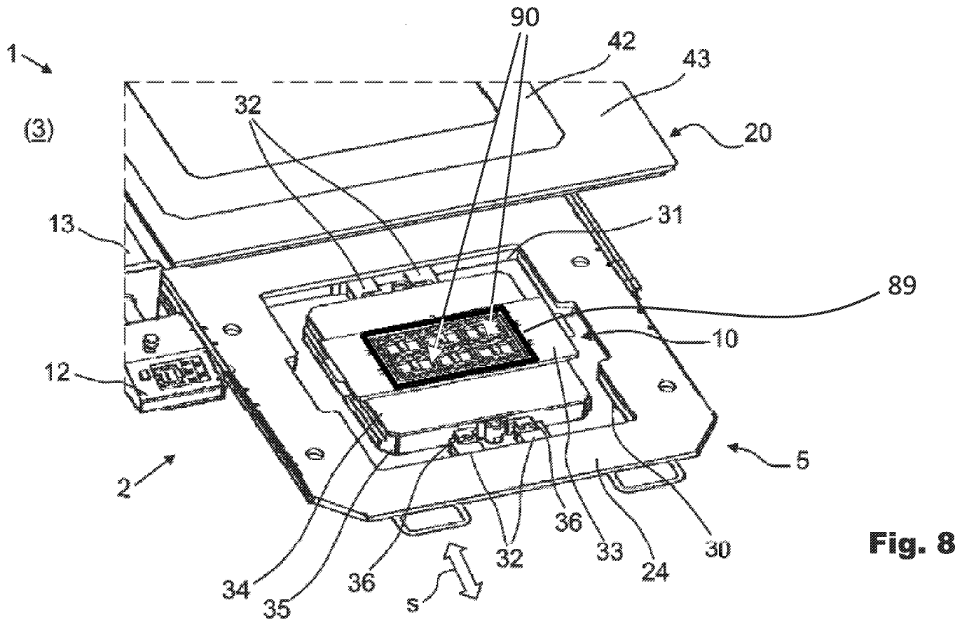

FIG. 8 The test system from FIG. 3 with a coupling device according to a second design example,

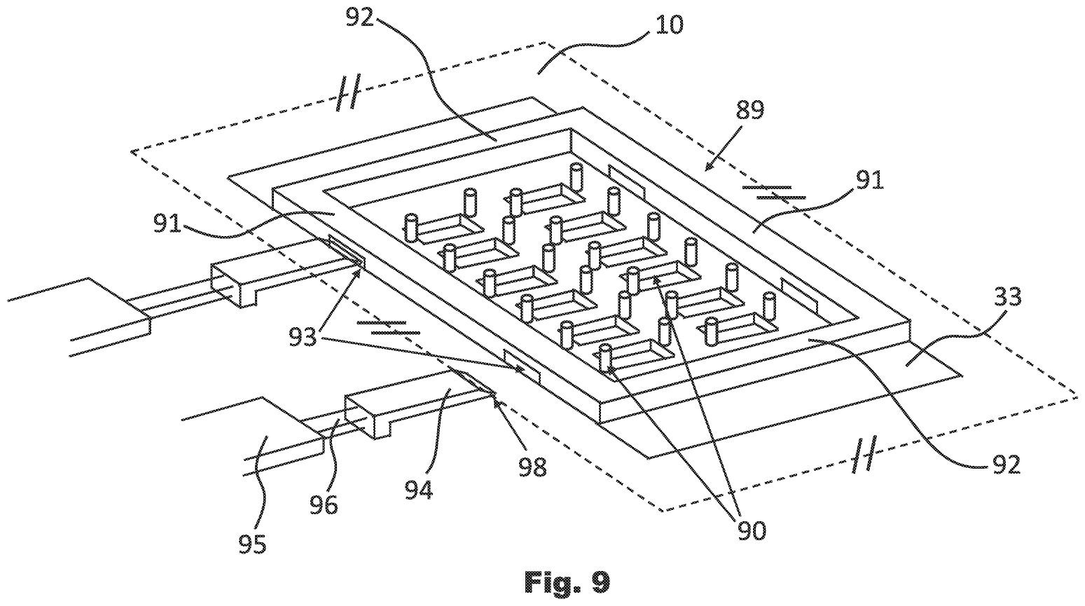

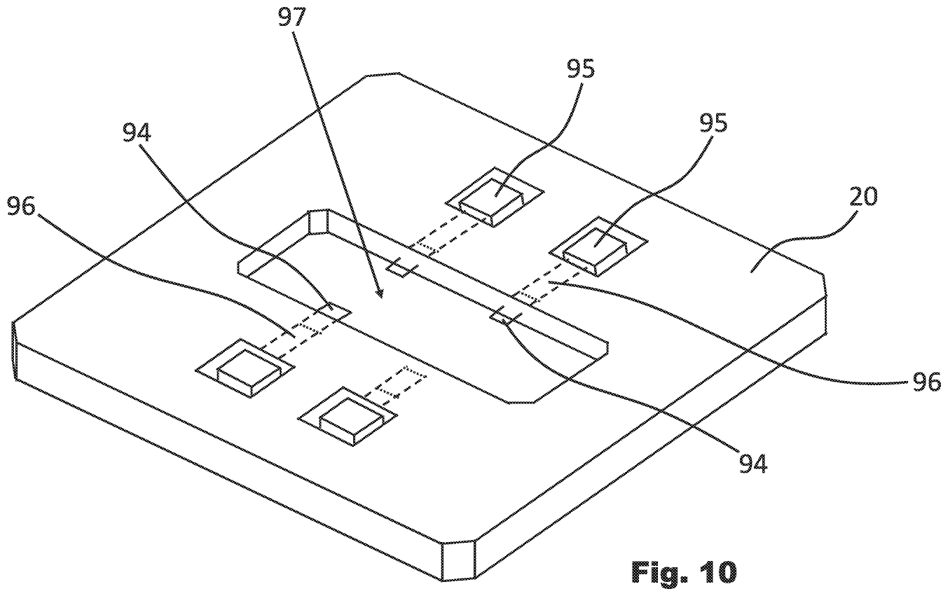

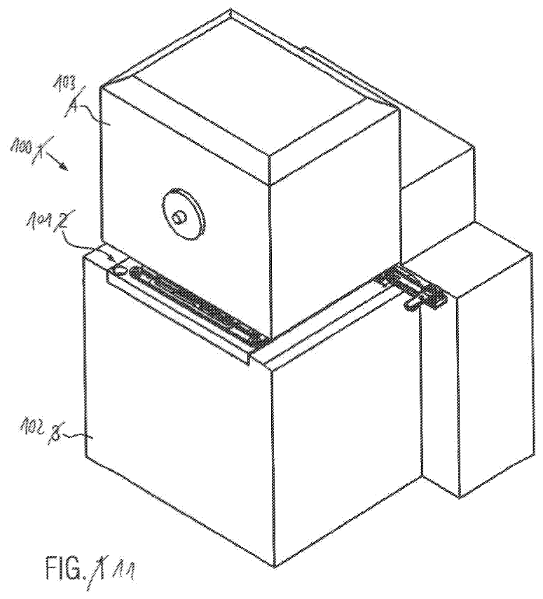

FIG. 9A schematic representation of an adapter frame on the interface unit according to the second embodiment example in a perspective view,

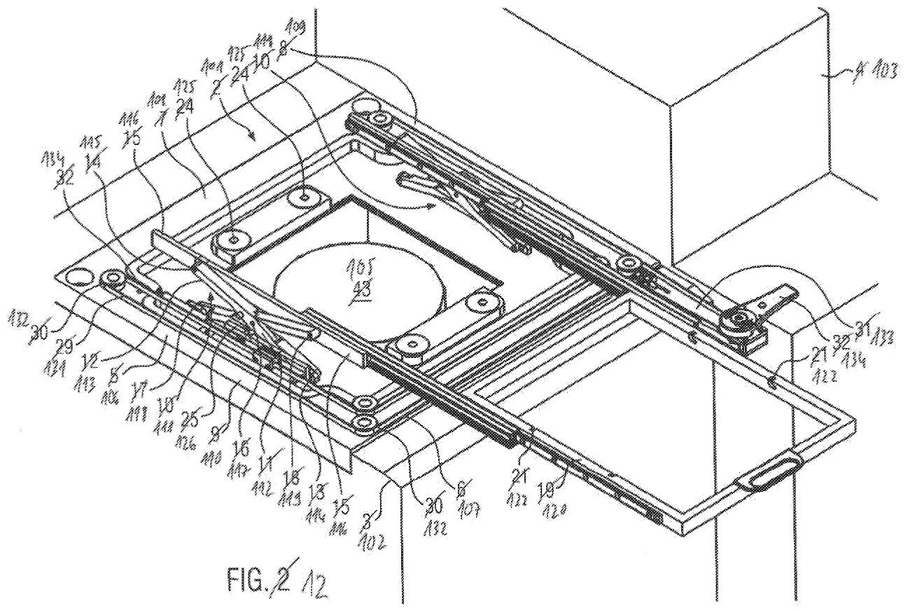

FIG. 10A schematic representation of a base element according to the second embodiment example,

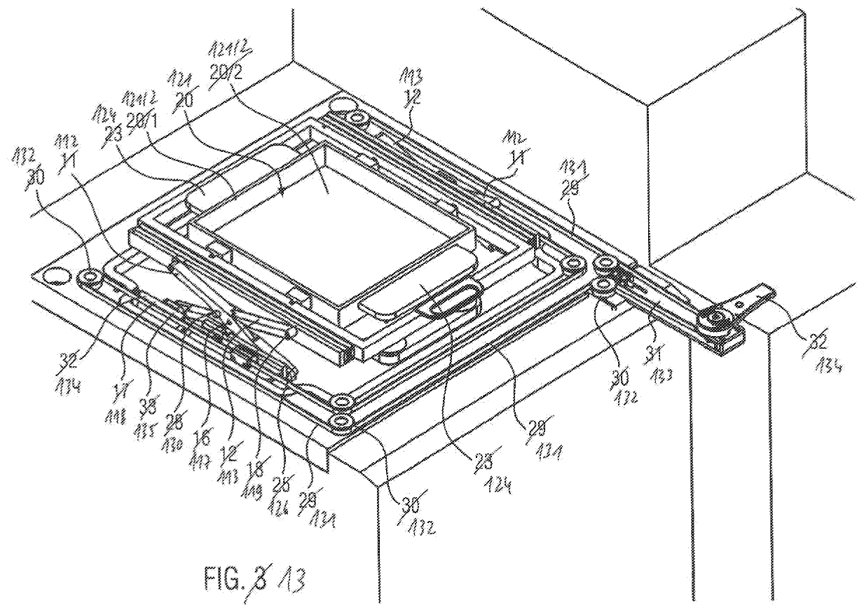

FIG. 11 FIG. 1 according to the document WO 2013/164407 A1,

FIG. 12 FIG. 2 according to document WO 2013/164407 A1 with a scissor mechanism in a fold-out position and a holding frame in a removal position,

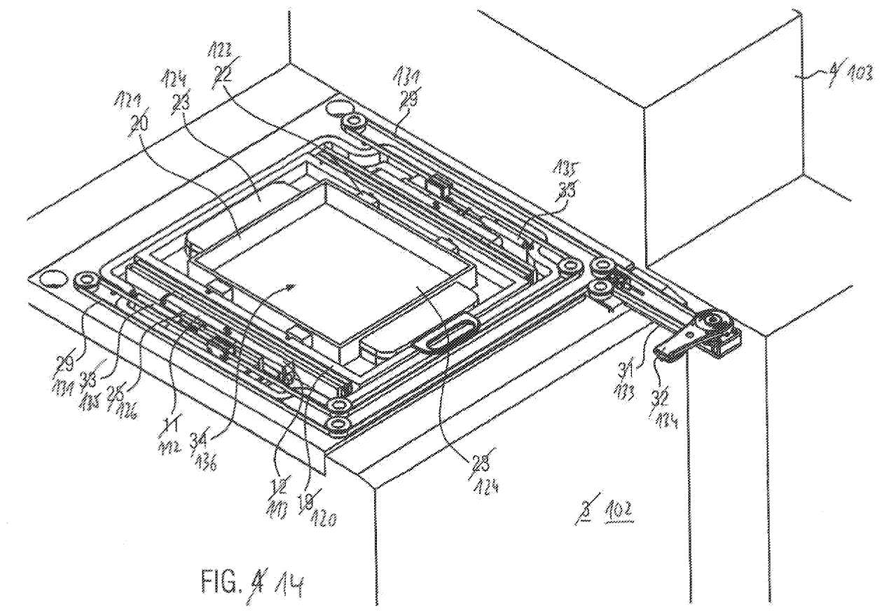

FIG. 13 FIG. 3 according to document WO 2013/164407 A1 with the scissor mechanism in the fold-out position and the holding frame in an inserted position,

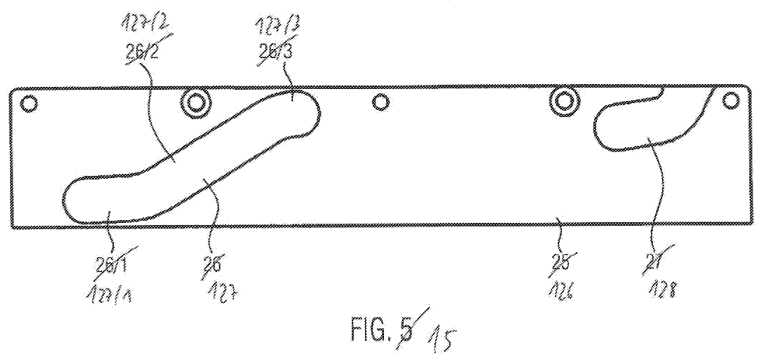

FIG. 14 FIG. 4 according to document WO 2013/164407 A1 with the scissor mechanism in the folded position and the holding frame in an end position,

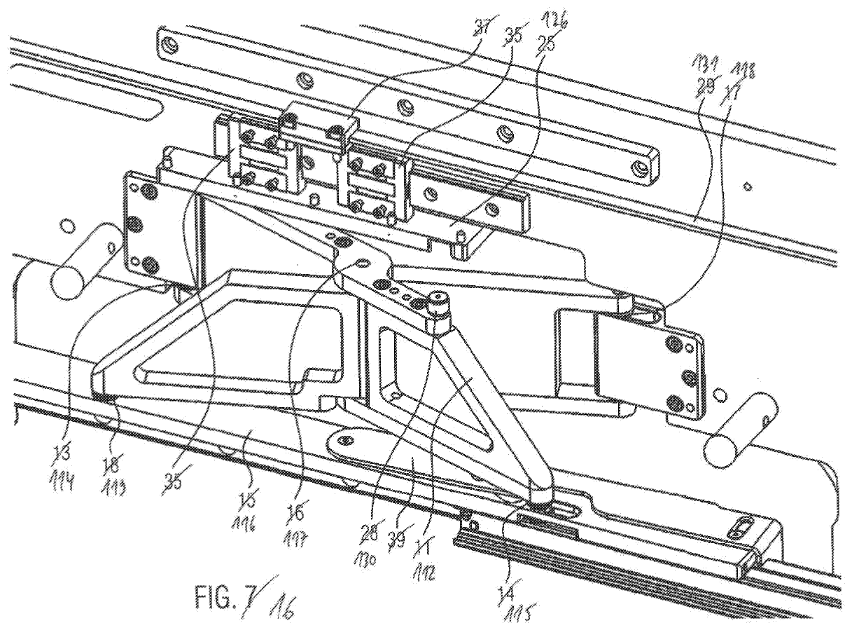

FIG. 15 FIG. 5 according to document WO 2013/164407 A1 with a schematic representation of curved paths,

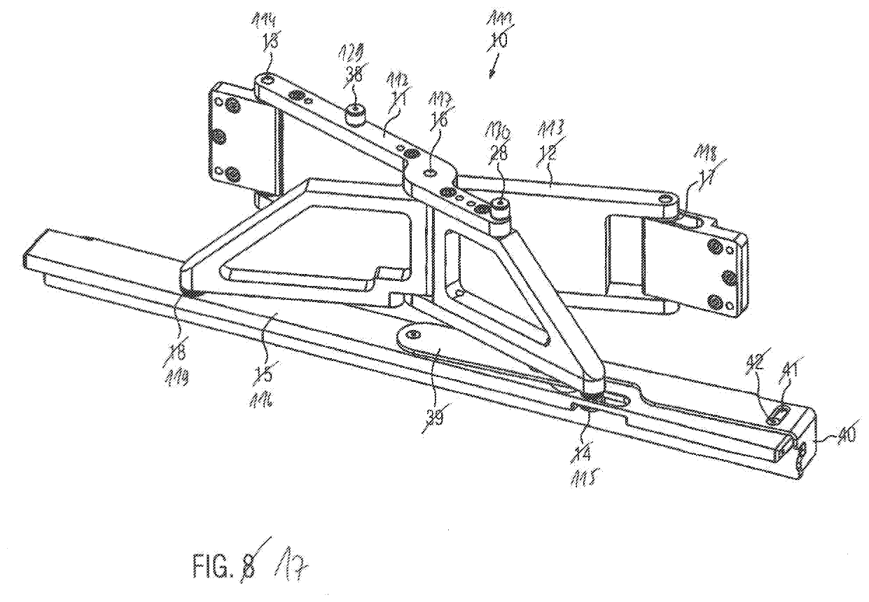

FIG. 16 FIG. 7 according to document WO 2013/164407 A1 with a detailed view of the scissor mechanism, and in

FIG. 17 FIG. 8 according to document WO 2013/164407 A1 with a further detailed view of the scissor mechanism.

FIG. 1 schematically shows a test system 1 for testing semiconductor elements with a first embodiment example of a module 2 according to the invention for exchanging an interface unit 10. FIGS. 2 to 4 show a first embodiment variant in more detail. FIGS. 5 and 6 show a second embodiment variant in more detail. When the terms “front” and “rear” or “right” and “left” are used in the following in relation to the test system 1, the module 2 or its components, these specifications are chosen from the viewing direction of an operator of the test system 1, unless otherwise defined in the individual case, since such a test system generally has one side from which an operator has access to the system, which in the present embodiment example in FIGS. 1 to 3, 5 and 6 is located approximately at the bottom right and in FIG. 7 on the right.

The term semiconductor elements includes semiconductor devices and wafers. The invention is explained below with reference to a test system 1 for semiconductor devices, but is also applicable to test systems for wafers.

The test system 1 has a handling unit 3 and a test unit 4. In operation, the handling unit 3 is a stationary unit, below which the test unit 4 is arranged (FIG. 1). More precisely, the test unit 4 can be moved into an area 6 left free in the lower section of the handling unit 3 and coupled to the handling unit. The module 2 for exchanging an interface unit 10 is arranged between the handling unit 3 and the test unit 4. This module 2 is referred to below as exchange module 2.

During operation, the handling unit 3 is used to feed semiconductor components to the interface unit 10. The semiconductor components held on the interface unit 10 are then tested by the test unit 4. The test can take a few seconds or up to several minutes.

During operation, the handling unit 3 and the test unit 4 are moved together and the interface unit 10 is fixed between them. Such a position of the interface unit 10 between the handling unit 3 and the test unit 4 is referred to as the test position.

The test position is the position in which the interface unit 10 is held in relation to the handling unit 3 so that the latter can fit the interface unit 10 with semiconductor elements.

Both the handling unit 3 and the test unit 4 are roughly box-shaped and have horizontal surfaces, between which the exchange module 2 is located, which is therefore arranged horizontally. This test system 1 is therefore referred to as a horizontal test system.

The interface unit 10 is usually made up of several parts. For example, the interface unit 10 has a base frame 33, a contacting plate (interface board) 34 and a stiffening plate (stiffener) 35 (FIG. 3). The structure and function of these elements of the interface unit 10 as well as the handling unit 3 and the test unit 4 were explained in the introduction to the description as background to the invention. These facts are in principle fully applicable to the present invention.

The exchange module 2 has a base element 20, which is attached to the test system 1 during operation (see FIGS. 2 to 7). In the present embodiment example, the base element 20 is attached to the handling unit 3. The exchange module 2 also has a holder 5, which is designed to hold the interface unit 10 and can be moved relative to the base element 20 by means of guide elements. The guide elements comprise a drawer mechanism 7 for translational, i.e., linear, guidance of the holder 5 in a pushing direction s, and a lifting mechanism 8 for translational, i.e., linear, guidance of the holder 5 in a lifting direction h. In the pushing direction s, which is a first direction in the sense of the invention, the holder 5 can be guided between an insertion position, in which the holder 5 is located in the test system 1 between the test unit 4 and the handling unit 3, and a removal position, in which the holder 5 is located outside the area 6 between the test unit 4 and the handling unit 3 for exchanging the interface unit 10. In the lifting direction h, which is a second direction in the sense of the invention, the holder 5 can be guided between an intermediate position, which corresponds to the insertion position, and an end position.

The removal position is a position in which the holder 5 holds the interface unit 10 ready for an operator outside the area 6, so that the operator can easily remove the interface unit 10. The pushing direction s runs along an interface plane, and the lifting direction h runs perpendicular or at least essentially perpendicular to the interface plane and thus perpendicular to the pushing direction s.

In a horizontal test system, the interface plane runs horizontally and is a plane that contains the interface unit 10 in use. The interface plane can be defined by a surface or other characteristic plane of the interface board 34 or a support surface or other characteristic plane of the stiffener 35 or a common support plane of the mounting elements of the base frame 33 of the interface unit 10.

Suitable design measures ensure that the lifting mechanism 8 can only be actuated when the drawer mechanism 7 is in the inserted position. Furthermore, devices are provided to ensure that the drawer mechanism 7 can only be actuated when the lifting mechanism 8 is in the intermediate position.

The base element 20 is a rigid, frame-shaped body, which can be made of aluminium or steel, for example, or possibly fibre-reinforced plastic. The base element 20 can advantageously have a modular structure with an inner frame 42 and an outer frame 43, whereby the inner frame 42 is arranged inside the outer frame 43 (see FIG. 4). The outer frame 43 is connected to the handling unit 3, and the inner frame 42 is firmly but detachably attached to the outer frame 43. The inner frame 42 can therefore be an interchangeable element.

The lifting mechanism 8, which supports the drawer mechanism 7, is attached to the inner frame 42.

Furthermore, the inner frame 42 can be approximately square in plan view, so that the inner frame 42 can be arranged in four orientations, each rotated by 90°, in the outer frame 43 and thus on the test system 1. If the test system 1 is a system that requires an interface plane parallel to the horizontal, then the inner frame 42 can be arranged in four 90° rotated orientations, whereby the inner frame 42 can be rotated about an axis perpendicular to the interface plane. This special configuration of the handling unit 3 with 90° adjustable positions of the drawer mechanism 7 represents a separate inventive concept that can also be used independently of the other functions and features in such a module 2 for exchanging interface units 10.

The holder 5 is also a rigid, frame-shaped body with a holding frame 24 as an essential component, which can be made of aluminium or steel, for example, or of optionally fibre-reinforced plastic or carbon, and which in the present case is formed in one piece, for example from a plate, but alternatively can also be constructed in several parts, for example from several struts. The holding frame 24 forms a window 27 in which the interface unit 10 can be received (see FIGS. 2, 3 and 6) and thus forms a receiving opening within the meaning of the invention. One or more handles 28 for manually moving the holder 5 in the pushing direction s can be provided on the front side of the frame 24.

The drawer mechanism 7 has a pair of guide rails 21 and a pair of runners 22. One guide rail 21 and one running rail 22 each form a telescopic rail 23. The running rails 22 run in the guide rails 21 and hold the holding frame 24 between them (FIG. 2). As described, the drawer mechanism 7 can be operated manually by means of the handles 28. Alternatively, the drawer mechanism 7 can also be operated by a motor, for example by an electromotive, electromagnetic, pneumatic or hydraulic or other type of drive.

The lifting mechanism 8 has a pair of universal joints consisting of a first and a second lever arm 45, 46, each extending between the base element 20 and one of the guide rails 21. More specifically, for each side (left, right) of the pair of universal joints, an upper or first lever bearing 80 is attached to the base element 20 and a lower or second lever bearing 47 is attached to the guide rails 21 of the drawer mechanism 7 (see FIGS. 4 and 7). Here, “top” as seen from the holding frame 24 is defined as a direction towards the base element 20, irrespective of the orientation of the exchange module 2 in space. The lever bearings 80, 47 can optionally also be designed as an integral part of the base element 20 or the guide rails 21. In this case, one end of each of the lever arms 45, 46 is fixedly but pivotably mounted on one of the lever bearings 80, 47 by means of a pivot joint 83 and the other end is longitudinally movably guided in an elongated hole 82 on the other of the lever bearings 80, 47 by means of a pivot joint 83, and the lever arms 45, 46 are pivotably connected to one another by means of a further pivot joint 83. The universal joint can be opened like a pair of scissors (FIGS. 1 and 7) or folded up. When the universal joint is opened and closed, the telescopic rail 23 with the holder 5 is raised or lowered relative to the base element 20. Here, the telescopic rail 23 is always arranged parallel to the surface of the base element 20. The lever arms 45, 46 can be moved relative to each other by any suitable means. These can be manually actuated by an actuating lever mechanism or motorised, for example by an electromotive, electromagnetic, pneumatic or hydraulic or other type of drive. In detail, the drawer mechanism 7 and the lifting mechanism 8, in particular the design, position and arrangement of swivel joints, the course of guide track(s) and the design of the swivel levers 45, 46 and their modifications, can follow the description and illustration in DE 10 2012 103 893 A1, to the disclosure content of which reference is made in full, also with regard to the design of the holder and the sequence of movements when the interface unit 2 is exchanged.

A drive unit 13 can be provided for motorised operation of the drawer mechanism 7 and/or the lifting mechanism 8 (see FIGS. 1 to 5). This can be started or stopped semi-automatically by means of an operating unit 12. Alternatively or additionally, the drive unit 13 can also be controlled by a control unit (not shown in detail or optionally integrated into the control unit 12), which automatically executes a predetermined movement program. For remote monitoring and/or remote control by a higher-level plant system, a radio antenna 14 can also be provided, which connects the control unit wirelessly to the plant system (see FIG. 1). A light indicator can be integrated into the radio antenna 14, which can indicate the operation of the test system 1, a fault or an expected operator intervention by means of corresponding light signals.

During the movement in the lifting direction h, centring pins 48, which project downwards from the base element 20, and centring holes 29, which are formed in the holding frame 24, can engage with each other. This enables secure positioning of the holding frame 24 and thus of the interface unit 10 relative to the base element 20 and thus relative to the test system 1.

According to the invention, one or more (here: four) docking elements 11 are attached, each of which forms a docking unit with a respective docking counter-element 40 (cf. FIGS. 4 and 7) attached to the base element 20. The docking units serve to couple the holder 5 to the base element 20 in such a way that a rigid connection is provided at least perpendicular to the interface plane between the holder 5 and the base element 20. In the embodiment example described here, the docking counter-elements 40 are attached to the inner frame 42 of the base element 20, which enables simple exchange, maintenance etc. and demonstrates a particular advantage of the modular structure of the base element 20.

The docking elements 11 and the docking counter-elements 40 together form a coupling device with which the holder 5 is coupled to the base element 20.

The docking elements 11 each have a mounting flange 84 and a locking pin 85 projecting from the mounting flange 84 (FIG. 7). The locking pin 85 has a circumferential groove 86. The mounting flange 84 is attached to the underside of the retaining plate 5 in such a way that the locking pin 85 projects upwards through a mounting opening 38 in the retaining plate 5. Once again, “up” is defined as a direction towards the base element 20 as seen from the holding frame 24, irrespective of the orientation of the exchange module 2 in space. The locking pin 85 can, but does not have to, protrude beyond the top of the retaining plate 5.

The docking counter-elements 40 each have a base section 87 and a catch section 88 projecting from the base section 87. The base section 87 is attached to the base element 20. In the assembled state, the catch section 88 points downwards from the base element 20 towards the retaining plate 5. It should be noted that the illustration in FIG. 7 is purely schematic and may show size relationships of components in a partially distorted manner. The catch section 88 is designed to receive the locking pin 85. The catch section can be inserted into the mounting opening 38 on the retaining frame 24. This allows the space requirement to be minimised.

The catch section 88 may comprise a locking unit (not shown in detail) for locking the docking element 11 to the docking counter-element 40. The locking unit may comprise a gripping mechanism and an actuating member. The gripping mechanism can be designed to grip the locking pin 85 at its circumferential groove 86 and to lock it by means of the actuating member. The gripping mechanism can, for example, be formed by a ball clamping sleeve which, in a first position, receives the locking pin 85 in an axially movable manner and, in a second position, is pressed into the circumferential groove 86. The actuating member can have a cylinder so that the ball clamping sleeve, which is surrounded by an annular pressure chamber that is sealed in a pressure-tight manner with respect to the insertion area of the locking pin 85 and can be moved in the axial direction by means of an annular piston, can be actuated by means of a pressure medium introduced into the pressure chamber through the cylinder. Such a locking unit with a fluid-actuated ball clamping sleeve is described in DE 10 2005 036 808 B4, the disclosure of which is referred to in its entirety in this respect. Simpler solutions with spindle-actuated ball clamping sleeves are described in DE 10 216 003 B4, to the disclosure of which reference is also made in full in this respect.

It may be provided that the docking units are designed not only for locking, but also for axially displacing the locking pin 85 relative to the docking counter-element 40. For this purpose, a pulling mechanism can be provided that linearly displaces the gripping mechanism of the docking counter-element 40 with the gripped locking pin 85 and pulls it towards the base element 20. If the axial displacement is small, only a final path in the stroke direction h can be executed to fix the holder in the end position.

However, the axial displacement can also be designed to be so large that the movement of the holder 5 with telescopic rails 23 in the lifting direction h can be realised completely or at least partially. Such docking units with linear displacement are described in DE 10 2012 112 271 A1, to whose disclosure reference is made in full in this respect. After release, the gripping mechanism can retract from the locking pin 85 back into the catch section 88 so as not to impede the movement of the holder 5 by means of the telescopic rails 23. In this case, the lever mechanism itself does not have to be driven; it is sufficient if the telescopic rails 23 are held securely in the intermediate position (the lower position of the lifting mechanism 8). In this case, the docking elements can be regarded as part of the lifting mechanism 8. The lever mechanism could then be replaced by a vertical guide with a depth stop and possibly locking in the intermediate position.

Insofar as reference is made to prior publications or prior applications with regard to the docking units, this applies essentially with regard to the functional and design principles described therein, insofar as applicable to the present application. The elements described there may have to be adapted to changed load conditions, assembly situations and dimensioning in the present application, or parts may have a fundamentally different design. Similarly, this also applies to references to prior publications or prior applications relating to the exchange module 2, whereby adjustments may also have to be made to the type of test device.

It should be noted that a coupling device 15 (see FIG. 1) can be provided on the test system 1, which is also based on the principle of the docking device as described in one of the aforementioned documents. This coupling device is used to connect a transport unit (trolley, not shown in detail), which can transport interface units and exchange them with the test system 1. Coupling by means of the coupling device 15 determines the relative position and, if necessary, interface units can be exchanged fully automatically between the transport unit and the holder in the removal position.

To accommodate the interface unit 10 on the holding frame 24, a front and a rear support element 30, 31 are provided in the embodiment variant shown in FIGS. 2 to 4, which are attached to the holding frame 24 so as to embrace the window 27. In this embodiment example, the support elements 30, 31 are C-shaped elements which are mounted on the holding frame 24 from below, which enables a particularly effective stiffening of the holding frame 24. However, the invention is not limited to the presence or the shape of the support elements 30, 31. The shape of the support elements 30 is to be designed according to the application and load case. The support elements 30, 31 have supports 32 which project into the window 27 of the holding frame 24 in the form of blocks. The stiffening plate 35 of the interface unit 10 has counter bearings 36 in the form of lugs that rest on the supports 32. Suitable centring and/or locking elements can be provided to fix the position (not shown in detail). In variations, the supports 32 and counter-bearings 36 can have any other suitable shape and can also be provided at other locations on the holding frame 24.

In one embodiment shown in FIGS. 5 and 6, a bridge element 50 is provided which spans the window 27 of the holding frame 24 (FIG. 5). The bridge element 50 is attached to the underside of the holding frame 24. The bridge element 50 can be a cast part or milled part made of aluminium or steel or another metal or a moulded part made of plastic or carbon, possibly fibre-reinforced, and is designed to be as rigid as possible against deflection. Even if the bridge element 50 in the present case spans the window 27 in the transverse direction, it can also span the window 27 in the longitudinal direction.

The interface unit 10 essentially rests on the bridge element 50 (FIG. 6, here the interface unit is shown with stiffening plate 35 and interface board 34, while the base frame and contact elements of the interface board 34 are omitted to simplify the illustration). In particular, the stiffening plate 35 rests on the bridge element 50. The stiffening plate 35 can have gripping elements 60 which, on the one hand, enable manual handling and which, on the other hand, can be used to fix the position on the holding frame 24. For this purpose, supports 51 can be provided, which are designed in the form of recesses on the holding frame 24 (FIG. 5). On the other hand, elevations 52 can be formed in the surface of the supports 51. The design can be chosen such that the gripping elements 60 can grip around the elevations 52 of the support 51 and otherwise rest on the supports 51. In this way, positive centring between the stiffening plate 35 and the holding frame 24 can be achieved at least in the interface plane. Spring-biased catches 53 can optionally be provided for locking perpendicular to the interface plane, and possibly also for centring.

The design variants with the stiffening elements 30, 31, on the one hand, and the bridge element 50, on the other serve to optimise the accommodation of different interface units. While the variant with stiffening elements 30, 31 is tailored to rather compact interface units with a correspondingly compact stiffening plate 35, the variant with bridge element 50 is tailored to rather flat interface units with a lighter stiffening plate 35. When using the bridge element 50, the stiffening elements 30, 31 of the previous embodiment variant can be omitted and vice versa. However, the embodiment can also be such that the bridge element 50 can be arranged in addition to the stiffening elements 30, 31. In this case, the stiffening elements 30, 31 do not necessarily have to be removed when the bridge element 50 is attached. If necessary, the bridge element 50 can also be attached or attachable to the stiffening elements 30, 31. The stiffening elements 30, 31 and the bridge element 50 can each be understood as parts of the holder 5, which can thus also have a modular structure, which can considerably improve the flexibility of use. Thus, when the interface unit 10 is exchanged, which requires a change to the holding and/or support system, it is possible to avoid dismantling the holding plate 24 from the telescopic rails 23 by attaching or removing the stiffening elements 30, 31 or the bridge element 50. It should be noted that for certain interface units 10 it may be possible to dispense with the use of both the stiffening elements 30, 31 and the bridge element 50.

The invention was explained above with reference to a test system 1 for semiconductor components. In other applications of the invention, the test system can also be designed for testing wafers. A handling unit for feeding wafer discs is referred to in the art as a “prober” and a handling unit for feeding individual integrated circuits is referred to as a “handler”. In test systems, also for testing wafers, the wafer discs are usually fed from below so that the handling unit is arranged below the test unit. The arrangement can therefore be rotated by 180°.

The embodiment example described above with its embodiment variants is designed as a horizontal test system, in which the interface unit is arranged horizontally between the test unit and the handling unit. The invention is not limited to this, rather the test system can be designed as a vertical test system, i.e., the handling unit and the test unit are arranged next to each other and the connecting sides in contact are aligned vertically. Accordingly, an interface unit, which is located between the handling unit and the test unit, must be arranged vertically with its interface level. With regard to a vertical test system, reference is also made in full to a corresponding embodiment example, which is described and shown in DE 10 2012 103 893 A1.

The invention relates to a module 2 for exchanging an interface unit 10 in a test system 1 with a handling unit 3 and a test unit 4 for testing semiconductor elements, as well as a test system 1 with a handling unit 3, a test unit for testing semiconductor elements, and the exchange module 2. The docking units can be used to couple the holder 5 securely and immovably to the base element 20 and thus to the test system 1 comprising test unit 4 and handling unit 3. The docking units can, for example, accommodate a load of at least 100 kg or at least 200 kg or at least 400 kg or at least 700 kg or at least 1000 kg. The load can be limited to a maximum of 1500 kg or a maximum of 900 kg or a maximum of 600 kg or a maximum of 300 kg or a maximum of 150 kg. The design load can be dependent on the pressurisation of a pneumatic actuating device, for example. In specific examples, the design load can be 500 kg or 1000 kg depending on the pneumatic pressure. This means that even high loads acting on the interface unit 10 due to the punching of semiconductor elements can be absorbed and channeled into the test system 1 itself.

The test system 1 enables a method for testing semiconductor elements, with the following steps:
picking up an interface unit 10 in the holder 5 in the removal position;
moving the holder 5 into the inserted position;
moving the holder 5 from the inserted position to the end position on the base element 20;
locking the holder 5 to the base element 20 by means of at least one docking unit, i.e., locking the respective docking element 11 to the respective docking counter-element 40;
moving the handling unit 3 and the test unit 4 together;
placing at least one semiconductor element on the interface unit 10 by means of the handling unit 3;
testing the at least one semiconductor element by means of the test unit 4; and
removing at least one semiconductor element from the interface unit 10 by means of the handling unit 3.

The steps of placing, testing and removing can then be repeated for a plurality of at least one semiconductor element.

The exchange module 2 enables a method for exchanging interface units 10 in the test system 1, with the following steps:
releasing the holder 5, which is in an end position, from the base element 20 by releasing a coupling state of at least one docking unit, i.e., releasing or unlocking the respective docking element 11 from the respective docking counter-element 40;
moving the holder 5 from the end position to the inserted position;
moving the holder 5 to the removal position;
removing the interface unit 10 from the holder 5;
picking up another interface unit 10 in the holder 5;
moving the holder 5 to the inserted position;
moving the holder 5 to the end position on the base element 20; and
locking the holder 5 to the base element by means of the at least one docking element.

A second embodiment example is explained below (FIGS. 8 to 17). Identical parts have the same reference signs as in the previous embodiment example. In addition, the above explanations apply equally to the corresponding parts of the second embodiment example. The second embodiment example differs from the first embodiment example in that no docking units are provided in the second embodiment example for coupling the holder 5 to the base element 20. Instead, a coupling device is provided between the interface unit 10 and the base element 20, which is described below.

An exchange module 2 is provided for exchanging an interface unit 10 in a test system 1 with a handling unit 3 and a test unit 4 for testing semiconductor elements.

The exchange module comprises a base element 20 and a holder 5, which is designed to accommodate an interface unit 10.

The holder 5 has a holding frame 24 with a window 27 in which an interface unit 10 can be accommodated.

The interface unit 10 comprises a stiffener plate (stiffener) 35, a contacting plate (interface board) 34 and a base frame 33.

The interface unit 10 forms an interface plane. The interface plane is a plane that runs parallel to a side of the interface unit 10 facing the base element 20.

On a side of the interface unit 10 facing the base element 20 of the exchange module 2, an adapter frame 89 is arranged on the base frame 33 (FIG. 8).

The adapter frame 89 is roughly rectangular in plan view and is firmly connected to the base frame 33. The adapter frame 89 is designed in such a way that it also surrounds receiving elements 90, arranged in a rectangle, of the base frame 33 of the interface unit 10.

The adapter frame 89 has two long adapter frame elements 91 running parallel to each other and two short adapter frame elements 92 moulded onto it running parallel to each other (FIG. 9).

The long adapter frame elements 91 each have two recesses. The recesses are formed as longitudinal through-holes 93. One of the through-holes 93 of the long adapter frame elements 91 is arranged in each case adjacent to one of the short adapter frame elements 92 and the other through-hole 93 is arranged in each case adjacent to the other of the short adapter frame elements 92. The through-holes 93 are aligned substantially parallel to the interface plane in terms of their length.

The through-holes 93 are each designed to accommodate corresponding longitudinal coupling elements. Latches 94 are provided as coupling elements. Instead of through-holes 93, blind-hole-shaped recesses can also be provided, which are delimited, for example, by the adapter frame 89 and the base frame 33.

Two or more lifting cylinders 95 are arranged on the base element 20 of the exchange module 2 and are firmly connected to the base element 20 (FIG. 10). The lifting cylinders 95 each have a piston rod 96, which can be moved linearly by the lifting cylinders 95. At a front end of each piston rod 96, is a latch 94 which is firmly connected to the piston rod 96.

The lifting cylinders 95 are arranged on the base element 20 in such a way that the latches 94 can be moved parallel to the interface level.

The base element 20 has an opening 97 in its centre, which is designed to accommodate the base frame 33.

If the holder 5 with the interface unit 10 is in an end position on the handling unit 3, then the adapter frame 89 together with the base frame 33 extends through the opening 97 of the base element 20 in such a way that one of the latches 94 of the lifting cylinders 95 can be moved into one of the through-holes 93 of the adapter frame 89.

By means of the latches 94, which are moved into the recesses 93, the interface unit 10 can be securely fixed to the base element 20 and thus to the handling unit 3.

The latches 94 each have an insertion bevel 98 at their end facing away from the piston rod 96. Due to the insertion bevels 98, the latches 94 slide into the through-holes 93, even if the adapter frame 89 is arranged with a slight vertical offset perpendicular to the interface plane on the base element 20. Thus, the latches 94 with the insertion bevels 98 simultaneously also ensure that such a vertical offset is compensated, since the latches 94 always push/pull the adapter frame 89 into the same (exact) end position on the base element 20 while they slide into the through-holes 93.

A scissor mechanism is provided to guide the holder 5 with the interface unit 10 from an inserted position, in which the holder 5 is located in the test system 1 between the test unit 4 and the handling unit 3, and the end position, in which the holder 5 with the interface unit 10 is arranged on the base element 20. Such a scissor mechanism is also known from DE 10 2012 103 893 A1 or WO 2013/164407 A1, to which reference is hereby made. The scissor mechanism can be folded flat, which is referred to as the end position, or it can also be unfolded so that it is extended, which is referred to as the unfolded position. The scissor mechanism is in the unfolded position when the holder 5 with the interface unit 10 is in the inserted position. The scissor mechanism is folded up in order to pull the holder 5 with the interface unit 10 towards the base element 20 and press the interface unit against it.

The term semiconductor elements includes semiconductor components and wafers. The test system 100 has a handling unit 102 (prober) and a test unit 103 (tester). In operation, the handling unit 102 is arranged below the test unit 103 (FIG. 11), with the module 101 for exchanging the interface unit 104 being arranged between the handling unit 102 and the test unit 103. This module 101 is referred to below as exchange module 101.

The handling unit 102 is used to feed wafers 105 to the interface unit 104. Both the handling unit 102 and the test unit 103 are roughly cuboid in shape, with the opposing side surfaces, between which the exchange module 101 is located, being arranged horizontally. This test system 100 is therefore referred to as a horizontal test system.

The exchange module 101 has a base element 106 that is attached to the test system 100. The base element 106 is attached to the handling unit 102. The base element 106 is a rigid frame-shaped body made of aluminium or steel, which is adapted to the contour of the handling unit 102. The base element 106 has a front and rear cross strut 107, 108 and a right and left longitudinal strut 109, 110. The positions “front” and “rear” or “right” and “left” are selected from the viewing direction of an operator of the test system 100, since such a test system 100 generally has one side from which an operator has access to the system, which in FIGS. 11 to 14 is located at the bottom right in the drawings. A lever mechanism 111 is attached to each of the inner sides of the longitudinal struts 109, 110. The two lever mechanisms 111 are of identical design, which is why only one of the two lever mechanisms 111 is explained below. The lever mechanism has a universal joint consisting of a first and a second lever arm 112, 113.

One end of the first lever arm 112 is attached to the inside of the longitudinal strut 109, 110 by a fixed swivel joint 114. The other end of the first lever arm 112 is attached to a telescopic rail 116 by a further swivel joint 115. The telescopic rail 116 is explained in more detail below. The swivel joint 115 is designed to be displaceable in the longitudinal direction of the telescopic rail 116. The first and second lever arms 112, 113 are pivotably connected to a pivot joint 117 approximately in their longitudinal centre.

One end of the second lever arm 113 is attached to the inside of the longitudinal strut 109, 110 by a swivel joint 118 that can be moved in the longitudinal direction of the longitudinal strut 109, 110. With its other end, the second lever arm 113 is fastened to the telescopic rail 116 with a further, stationary swivel joint 119.

The universal joint can be unfolded like a pair of scissors (FIGS. 12 and 13) or folded up (FIG. 14). When the universal joint is opened and closed, the telescopic rail 116 is raised or lowered with respect to the base element 106. Here, the telescopic rail 116 is always arranged parallel to the respective longitudinal strut 109, 110.

Since the two stationary swivel joints 114, 119 are arranged opposite one another and the sections of the lever arms 112, 113 from the common swivel joint 117 to the swivel joints 114, 115, 118, 119, with which the lever arms 112, 113 are articulated to the base element 106 and to the telescopic rail 116, are each the same length, the movement when opening and closing the universal joint of the telescopic rail 116 is rectilinear. The universal joint thus forms a straight-line guide, since it guides the telescopic rail 116 along a rectilinear path of movement.

The two telescopic rails 116 hold a holding frame 120, which forms a holder for holding an interface unit 104. The interface unit 104 is formed from a stiffening frame 121/1 and an interface board 121/2. By means of the telescopic rails 116, the holding frame 120 is mounted in a displaceable fashion so that it can be pulled out of the area above the handling unit 102. The holding frame 120 has recesses 122 into which protruding projections 123 on the interface unit 104 can be inserted, so that the interface unit 104 is held in the holding frame 120. Two retaining plates 124 protrude from the outside of the stiffening frame 121/1 of the interface unit 104. Two downwardly projecting positioning pins are arranged on each of the retaining plates 124. The positioning pins can engage in corresponding positioning bushes 125. The positioning bushes 125 are attached to the handling unit 102. The positioning pins and the positioning bushes 125 form a pneumatically operable positioning system (docking system) and are designed in accordance with U.S. Pat. No. 6,870,362 B2.

The lever mechanisms 111 are each coupled to a link 126. The link 126 is linearly mounted in a displaceable fashion on the base element 106. The link 126 has a first cam track 127 and a second cam track 128. The first cam track 127 is referred to below as swivelling cam track 127 and the second cam track 128 as locking cam track 128. The cam tracks 127, 128 are elongated recesses in the link 126, in which the first lever arm 112 engages with a pivot pin 129 (FIG. 15) and a locking pin 130.

The two links 126 are of identical design and are coupled to a drive belt 131, which is guided by means of a plurality of deflection rollers 132 arranged on the base element 106 in such a way that in each case a section of the drive belt 131 extends along one of the two lever mechanisms 111 and in each case one of the two links 126 is coupled to these sections of the drive belt 131, so that when the drive belt 131 is moved, both links 126 are displaced in a straight line by the drive belt 131. The drive belt 131 is a toothed belt. However, it can also be designed as a chain, steel cable or rod mechanism.

A strip 133 is arranged on the base element 106, which protrudes a little on the front side of the base element 106. An actuating lever 134, which is provided with a catch device, is arranged at the far end of the strip 133. The actuating lever 134 is coupled to a pinion which meshes with the drive belt 131 so that the drive belt 131 is moved when the pinion is rotated by means of the actuating lever 134. The strip 133 protrudes so far from the base element 106 that the actuating lever 134 is freely accessible even when the test system 100 is closed.

Instead of the actuating lever 134, an automatic actuating device, such as a pneumatic lift/piston mechanism, may also be provided to move the drive belt 131.

A spring device 135, which is a gas pressure spring 135, is coupled between the drive belt 131 and the base element 106. One end of the gas pressure spring 135 is attached to one of the two links 126 and the other end is attached to the base element 106.

In FIG. 14, the adapter 121 is shown in an end position in which the positioning pins engage in corresponding positioning bushes 125 and are fixed therein. In this end position, the interface unit 104 is in the position required to operate the test system 100. In FIG. 14, the interface unit 104 is shown with a schematically simplified interface board 121/2. The plane in which the interface board 121/2 is located in the end position is referred to below as the interface plane 136.

The swivelling cam track 127 (FIG. 15) has a first flat section 127/1, a more inclined section 127/2 and a second flat section 127/3. The inclination of the three sections 127/1, 127/2, 127/3 relates to the interface plane 136, i.e., the flat sections 127/1 and 127/3 have only a very slight inclination with respect to the interface plane 136 and the inclined section 127/2 has a greater inclination with respect to the interface plane 136. In the following, the first flat section 127/1 is referred to as the first locking section 127/1, the inclined section 127/2 is referred to as the actuating section 127/2 and the second flat section 127/3 is referred to as the second locking section 127/3. When the link 126 is displaced, the pivot pin 129 of the lever arm 112 slides in the pivot cam path 127 such that when the pivot pin 129 slides from the first locking section 127/1 along the actuating section 127/2 to the second locking section 127/3, the pivot pin 129 is lifted and thus the lever arm 112 is pivoted about the pivot joint 117.

The swivelling movement is performed primarily by the interaction of the swivel pin 129 and the actuating section 127/2. The locking sections 127/1 and 127/2 are designed to be so flat that they cause no or only a very slight swivelling movement. During this swivelling movement, in which the swivel pin 129 slides from the first locking section 127/1 along the actuating section 127/2 to the second locking section 127/3, the universal joint is opened and the holding frame 120 with the adapter 121 is lifted upwards from the end position into an intermediate position (FIG. 13). Because the second locking section 127/3 is very flat, the universal joint is locked in this intermediate position by the link 126.

In this intermediate position, the holding frame 120 and the adapter 121 can be pulled out of the area above the handling unit 102 by means of the telescopic rails 116. The holding frame 120 and the adapter 121 are then in a removal position (FIG. 12), in which the adapter 121 can be easily replaced by a user. Devices are provided which prevent the telescopic rails 116 from being pulled out when they are not in the intermediate position. These devices are not shown in the schematically simplified FIGS. 11 to 14.

If the link 126 is moved back so that the pivot pin 129 slides from the second locking section 127/3 along the actuating section 127/2 to the first locking section 127/1, then the lever arm 112 is swivelled downwards so that the universal joint is closed. This closed position (FIG. 14) represents the end position. When the lever arm is lowered, the locking pin 130 engages in the locking cam track 128, which has an upwardly open aperture and runs flat with respect to the interface plane 136 (=slight inclination with respect to the interface plane 137). The locking pin 130 and the locking cam track 128 are further away from the swivel joint 117 than the swivel pin 129 and the corresponding swivel cam track 127, so that a stronger additional locking of the universal joint in the end position is achieved due to the longer lever. The locking pin 130 and the locking cam track 128 provide additional fixation of the telescopic rails 116 and prevent them from bending. It may therefore be possible to fulfil the required tolerances even without a positioning system comprising the positioning pins and the positioning bushes 125. This applies in particular to test systems 100 for testing semiconductor components, since the tolerances here are greater than for test systems 100 for testing wafers 105.

During lowering, the gas pressure spring 135 is tensioned so that the gas pressure spring 135 counteracts the weight of the holding frame 120, the adapter 121 and the interface unit 104. This allows the actuating lever 134 to be actuated with little force in order to move the module 101 from the end position (FIG. 14) to the intermediate position (FIG. 13) and back again. The latching device of the actuating lever 134 has at least latching positions for the end position and the intermediate position, so that in conjunction with the locking effect of the swivelling cam track 127 and the locking cam track 128, the exchange module 2 is held securely in the end position or in the intermediate position.

In the intermediate position, the holding frame 120 can be pulled out by means of the telescopic rails 116 in order to replace the adapter 121 with the interface unit 104. The straight-line guidance of the universal joint with the lever arms 112, 113 ensures that the positioning pins are correctly inserted into or removed from the positioning sockets 125 and, if further contact pins are provided on the interface unit 104, that these are not damaged. The test system 100 is a test system for testing wafers 105, which are fed to the interface unit 104 with a handling unit (prober) 102. The test system can also be designed for testing semiconductor components. A handling unit for feeding wafer discs is referred to in the art as a “prober” and a handling unit for feeding individual integrated circuits is referred to as a “dealer”.

Folding in the scissor mechanism pulls the holding frame 120 towards the base element 106 and presses it against the base element 106. During the process of folding in the scissor mechanism, the pivot pin 129 on the first lever arm 112 moves along the pivot curve path 127 of the link 126 on the base element 106 from the second locking section 127/3 in the direction of the first locking section 127/1.

Once the pivot pin 129 has arrived approximately in the region of the first locking section 127/1, the locking pin 130 couples into the locking cam track 128 of the link 126 on the base element 106 in order to generate an additional moment of force so that the retaining frame 120 is pressed firmly against it.

In the present invention, the adapter frame 89 is provided, which strikes against the base element 20 on the handling unit 3 when the holder 5 with the interface unit 10 approaches. As a result, the scissor mechanism cannot always fully retract. This is particularly the case with thick base frames 33 of the interface unit 10.

In the scissor mechanism with the cam tracks (swivelling cam track and locking cam track), in which the pins (swivelling pin and locking pin) engage and are guided along, a high force torque can be generated even if the scissor mechanism is not fully retracted. The locking pin engages sufficiently early in the locking cam path so that a large moment of force can be exerted by the scissor mechanism on the holder 5 with the interface unit 10 even if the base frame 33 of the interface unit 10 is thick and the adapter frame 89 hits the handling unit 3 prematurely as a result. The force torque can be adjusted by the inclination of the locking cam track and the swivelling cam track. FIG. 15 shows an exemplary configuration of the cam tracks. The flatter the cam tracks are, the greater the moment of force but the shorter the travel distance. The cam track must be adapted to the respective requirements.

By engaging the locking pin 130 in the locking cam track 128, the rigidity of the scissor mechanism is increased and an additional moment of force is exerted.

In this way, the holder 5 with the interface unit 10 can also be pressed firmly against the base element 20 with this configuration of the scissor mechanism in combination with the coupling device, which requires the adapter frame 89.

According to the second embodiment example, the test system 1 enables a method for testing semiconductor elements, comprising the steps:
picking up an interface unit 10 in the holder 5 located in the removal position;
moving the holder 5 with the interface unit 10 into the inserted position;
moving the holder 5 with the interface unit 10 from the inserted position to the end position on the base element 20;
locking the interface unit 10 to the base element 20 by means of the adapter frame 89 and the at least one latch 94, i.e., locking by engaging at least one latch 94 in at least one through-hole 93 of the adapter frame 89;
moving the handling unit 3 and the test unit 4 together;
placing at least one semiconductor element on the interface unit 10 by means of the handling unit 3;
testing at least one semiconductor element by means of the test unit 4; and
removing at least one semiconductor element from the interface unit 10 by means of the handling unit 3.

The steps of placing, testing and removing can then be repeated for a large number of semiconductor elements of the same type.

According to the second embodiment example, the exchange module 2 enables a method for exchanging interface units 10 in the test system 1, with the steps:
releasing the holder 5 in an end position with the interface unit 10 from the base element 20 by releasing a coupling state of the at least one latch 94 with at least one through-hole 93 of the adapter frame 89, i.e., releasing or disengaging at least one latch 94 with at least one through-hole 93 of the adapter frame 89;
moving the holder 5 with the interface unit 10 from the end position to the inserted position;
moving the holder 5 with the interface unit 10 to the removal position;
removing the interface unit 10 from the holder 5;
picking up another interface unit 10 in the holder 5;
moving the holder 5 with the other interface unit 10 to the inserted position;
moving the holder 5 with the other interface unit 10 to the end position on the base element 20; and
locking the holder 5 with the other interface unit 10 to the base element by means of the adapter frame 89 and at least one latch 94.

The second embodiment example has a scissor mechanism and a locking mechanism with latches. Within the scope of the invention, the scissor mechanism can be provided in the first embodiment example in the same way as in the second embodiment example, whereby here the holder frame can be fixed to the base element by means of the docking elements.

The scissor mechanism allows a very compact design of the module for exchanging the interface unit, which can be positioned entirely in the area between a test unit and a handler/prober. Modules for exchanging interface units are also known that use lifting cylinders as the lifting mechanism. However, these lifting cylinders must be arranged in an area outside the tester and/or the handler/prober, i.e., the entire module protrudes laterally at least on the test unit and/or the handler/prober. This additionally increases the space requirement of such a test system and makes it difficult to interact with other external components, such as a travelling device (trolley).

### LIST OF REFERENCE SYMBOLS

1 Test system
2 Exchange module (module)
3 Handling unit (handler, prober)
4 Test unit (tester)
5 Holder
6 Area
7 Drawer mechanism
8 Lifting mechanism
9 Front cover
10 Interface unit
11 Docking element
12 Control unit
13 Drive unit
14 Radio antenna/light indicator
15 Coupling device
20 Basic element
21 Guide rail
22 Rail
23 Telescopic rail
24 Holding frame
27 Opening (window)
28 Handle
29 Centring hole
30 Front support element
31 Rear support element
32 Support
33 Base frame
34 Contacting plate (interface board)
35 Stiffening plate (stiffener)
36 Counter bearing
38 Mounting opening
40 Docking counter-element
42 Inner frame
43 Outer frame
45 First lever arm
46 Second lever arm
47 Lower lever bearing
48 Centring bolt
50 Bridge element
51 Support
52 Elevation
53 Snap bolt
60 Handle elements
80 Upper lever bearing
81 Bearing hole
82 Oblong hole
83 Pivot joint
84 Mounting plate
85 Locking pin
86 Circumferential groove
87 Basic section
88 Catch section
89 Adapter frame
90 Mounting elements
91 Long adapter frame element
92 Short adapter frame element
93 Through-hole
94 Latch
95 Lifting cylinder
96 Piston rod
97 Opening
98 Insertion bevel
100 Test system
101 Module (exchange module)
102 Handling unit
103 Test unit
104 Interface unit
105 Wafer
106 Base element
107 Front cross strut
108 Rear cross strut
109 Right longitudinal strut
110 Left longitudinal strut
111 Lever mechanism
112 Lever arm
113 Lever arm
114 Swivel joint
115 Swivel joint
116 Telescopic rail
117 Swivel joint
118 Swivel joint
119 Swivel joint
120 Holding frame
121 Adapter
122 Recess
123 Protrusion
124 Retaining plate
125 Positioning bushes
126 Link
127 Swivelling curve track
128 Locking cam track
129 Pivot pin
130 Locking pin
131 Drive belt
132 Idler pulley
133 Moulding
134 Operating lever
135 Spring device
136 Interface level
S Thrust direction
h Stroke direction

The above list is an integral part of the description.

1. Module for exchanging an interface unit in a test system having a handling unit and a test unit for testing semiconductor elements, the module comprising:
a base element attached or attachable to the test system,
a holder for receiving an interface unit, and
guide elements which connect the holder to the base element and are designed to guide the holder relative to the base element between an insertion position, in which the holder is located in the test system between the test unit and the handling unit, and a removal position, in which the holder is located outside an area between the test unit and the handling unit for exchanging the interface unit,
wherein a coupling device is provided for coupling the interface unit to the base element, wherein the coupling device is either arranged
between the holder and the base element for coupling the holder to the base element in such a way that the coupling device can form a rigid connection at least perpendicular to an interface plane, or
the coupling device is arranged on the interface unit and on the base element so that the interface unit can be fixed to the base element.

2. Module according to claim 1, wherein the coupling device is designed as at least one docking unit each having a docking element and a docking counter-element for coupling the holder to the base element in such a way that the coupling device provides a rigid connection at least perpendicular to the interface plane, wherein the docking element or the docking counter-element is attached to the holder and the docking counter-element or the docking element is attached to the base element and the docking unit is designed for mechanically connecting and disconnecting the docking element to the docking counter-element.

3. Module according to claim 1, wherein the guide elements comprise a drawer mechanism with a pair of telescopic rails, for linearly guiding the holder relative to the base element in a first direction of movement, wherein the first direction of movement extends in or parallel to the interface plane.

4. Module according to claim 1, wherein the guide elements comprise a lifting mechanism, in particular a lever mechanism or scissor mechanism, for linearly guiding the holder relative to the base element in a second direction of movement, wherein the second direction of movement is substantially perpendicular to the first direction of movement and substantially perpendicular to the interface plane.

5. Module according to claim 1, wherein a drive mechanism is provided for motorised, in particular automatically or semi-automatically controlled, movement of the holder relative to the base element under the guidance of the guide elements.

6. Module according to claim 2, wherein several docking units are provided for connecting the drawer unit and the base element.

7. Module according to claim 2, wherein the docking unit(s) can be actuated pneumatically and/or electrically and/or magnetically, in particular electromagnetically, for connection or disconnection.

8. Module according to claim 2, wherein the docking element of each docking unit has a locking pin and the docking counter-element of each docking unit has a locking element which engages in a catch provided on the locking pin, which catch is designed in particular as a circumferential groove.

9. Module according to claim 8, wherein the locking element has a gripping mechanism which engages in the catch, wherein the gripping mechanism preferably has a plurality, in particular at least three, of balls, between which the locking pin can be inserted, and a ball clamping sleeve which can be displaced in the axial direction and which can fix the balls in the catch or release them from the catch by axial displacement.

10. Module according to claim 9, wherein the gripping mechanism is connected to a pulling mechanism designed to pull the gripping mechanism along an axis of the locking pin.

11. Module according to claim 1, wherein the base element is attached or attachable to the test unit or the handling unit.

12. Module according to claim 1, wherein the base element comprises an outer frame and an inner frame, wherein the outer frame is attached or attachable to the test unit or the handling unit, and wherein the inner frame is attached or attachable to the outer frame.

13. Module according to claim 2, wherein the docking counter-element or the docking element of the at least one docking unit is mounted on the inner frame.

14. Module according to claim 1, wherein the holder has a holding frame, wherein the interface unit can be accommodated in a receiving opening formed by the holding frame.

15. Module according to claim 14, wherein the holding frame has at least two supports projecting opposite one another into the receiving opening for receiving an interface unit.

16. Module according to claim 14, wherein a bridge element is provided which is attached or can be attached to the holding frame so as to span the holding opening of the holding frame and which is designed to hold or support an interface unit or an interface unit carrier or a stiffening element.

17. Module according to claim 14, wherein locking elements, preferably spring-biased latching catches, are provided on the holding frame for locking the interface unit arranged on the bridge element relative to the holding frame.

18. Module according to claim 1, wherein the coupling device comprises an adapter frame with at least one recess and at least one movable coupling element for coupling the interface unit to the base element such that the coupling provides a releasable positive connection parallel to the interface plane, wherein the adapter frame is attached to the interface unit and the at least one movable coupling element is attached to the base element, and wherein the movable coupling element engages in the recess to provide a releasable mechanical connection between the interface unit and the base element.

19. Test system comprising a handling unit and a test unit for testing semiconductor elements, wherein the test system comprises a module according to claim 1.

20. Method for testing semiconductor elements by means of a test system having a test unit, a handling unit for handling semiconductor elements and a module for exchanging interface units, the module comprising a base element which is fastened to the test system, a holder for receiving an interface unit, and guide elements which connect the holder to the base element and are formed to guide the holder relative to the base element between an inserted position, in which the holder is located in the test system between the test unit and the handling unit, and a removal position, in which the holder is located outside an area between the test unit and the handling unit for exchanging the interface unit, and is designed in particular according to claim 1, with the following steps:
picking up an interface unit in the holder located in the removal position;
moving the holder with the interface unit into the insertion position;
moving the holder with the interface unit from the inserted position to an end position on the base element;
coupling the interface unit to the base element by means of a coupling device, wherein the coupling device is either
arranged between the holder and the base element for coupling the holder to the base element in such a way that the coupling device can form a rigid connection at least perpendicular to an interface plane, or
the coupling device is arranged on the interface unit and on the base element so that the interface unit can be fixed to the base element;
moving the handling unit and the test unit together;
placing at least one semiconductor element on the interface unit by means of the handling unit;
testing the at least one semiconductor element by means of the test unit; and
removing the at least one semiconductor element from the interface unit by means of the handling unit,
wherein the steps of placing, testing and removing are repeated for a plurality of at least one semiconductor element.

21. Method for exchanging interface units on a test system with a test unit, a handling unit for handling semiconductor elements and a module for exchanging interface units, wherein the module comprises a base element attached to the test system, a holder for receiving an interface unit, and guide elements which connect the holder to the base element and are formed to guide the holder relative to the base element between an inserted position, in which the holder is located in the test system between the test unit and the handling unit, and a removal position, in which the holder is located outside an area between the test unit and the handling unit for exchanging the interface unit, and is designed in particular according to claim 1, with the steps of
releasing the holder located in an end position with the interface unit from the base element by releasing a coupling state of a coupling device, wherein the coupling device either
is arranged between the holder and the base element for coupling the holder to the base element in such a way that the coupling device can form a rigid connection at least perpendicular to an interface plane, or
the coupling device is arranged on the interface unit and on the base element so that the interface unit can be fixed to the base element;
moving the holder with the interface unit from the end position to the inserted position;
moving the holder with the interface unit to the removal position;
removing the interface unit from the holder;
picking up another interface unit in the holder;
moving the holder with the other interface unit to the inserted position;
moving the holder with the other interface unit to the end position on the base element; and
locking the holder with the other interface unit to the base element by means of the coupling device.
